(19) United States
(12) Patent Application Publication
(10) Pub. No.: US 2010/0173448 A1
(43) Pub. Date: Jul. 8, 2010

(54) HIGH FREQUENCY PLASMA ENHANCED CHEMICAL VAPOR DEPOSITION

(75) Inventor: Soo Young Choi, Fremont, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/349,789

(22) Filed: Jan. 7, 2009

(51) Int. Cl. H01L 31/18; H01L 21/70; H01L 21/44

(52) U.S. Cl. 438/96; 438/479; 438/97; 257/E21.535; 257/E21.476

(57) ABSTRACT

The present invention generally comprises a method for forming a thin film transistor device in a capacitively coupled PECVD processing chamber. The method comprises forming an active layer on a substrate by a method comprising depositing a silicon nitride layer adjacent to the substrate with a first frequency power source, and depositing a semiconductor layer adjacent to the silicon nitride layer with a second frequency power source, and forming a passivation layer adjacent to the active layer by a method comprising depositing a silicon nitride layer adjacent to the semiconductor layer with the first frequency power source.

### BACKGROUND OF THE INVENTION

1. Field of the Invention

Embodiments of the present invention generally relate to a method of improving film quality of TFT devices or tandem junction solar cells while substantially maintaining film uniformity in light of the electromagnetic effects occurring at high frequencies.

2. Description of the Related Art

Current interest in thin film transistor (TFT) arrays is particularly high because these devices are used in liquid crystal active matrix displays (LCDs) within computer and television flat panels. The liquid crystal active matrix displays may also contain light-emitting diodes (LEDs) for back lighting. As an alternative to LCD displays, organic light-emitting diodes (OLEDs) have also been used for active matrix displays, and these organic light-emitting diodes require TFTs for addressing the activity of the displays.

As the size of substrates continues to grow in the TFT-LCD industry, the requirement for TFT driving frequency gets higher from 60 Hz to 120 Hz, 180 Hz or 240 Hz in order to reduce RC delay of longer signal lines, which however, requires faster TFT switching characteristics. A faster switching speed can usually be achieved by increasing the electron mobility of a transistor since switching speed of a TFT is known to be proportional to the mobility of the majority carrier. However, improving electron mobility cannot be easily obtained with conventional amorphous silicon TFT device that has the mobility less than 1 cm²/Vs and hence requiring improvement of semiconductor material quality.

In recent years, low temperature polysilicon (LTPS) TFT and micro-crystalline silicon TFT have been developed to offer an operation speed faster than that of the amorphous silicon TFT. Although LTPS TFT is able to provide higher carrier mobility, it is limited to small size application due to difficulty of conventional laser annealing process. Conventional laser annealing LTPS-TFT process has proven to be unsatisfactory because the resulting silicon grain structure after re-crystallization lacks uniform structure. Micro-crystalline silicon is therefore getting more attention to OLED backplane application as it was found that micro-crystalline silicon devices could achieve a mobility greater than 1 cm²/Vs and even higher than 2 cm²/Vs.

Very high frequency (VHF) has the advantage of maintaining high-density plasma under a low self-bias voltage, and therefore is used to obtain high quality micro-crystalline silicon at high deposition rate. The thinner plasma sheaths obtained at higher frequencies can result in a lower sheath potential, thereby reducing ion bombardment and plasma damage to the growing surface. However, there are pros and cons to PECVD film growth technology using VHF excitation. One of the issues for large substrate sizes and high-density plasma sustained using very high frequency is the nonuniformity of film thickness due to plasma standing wave effect. This standing wave phenomenon is becoming more pre-dominant because when the size of the substrate increases, plasma reactors are also becoming larger to a point where the size of the reactor is no longer negligible. In a plasma environment using very high frequency, the electromagnetic wavelength is reduced by approximately a factor of 5 from its free space wavelength, such that its quarter wavelength may approach the dimensions of the plasma chamber and causing a radial spread electromagnetic wave, i.e., standing wave. As a result, the plasma density along the reactor can no longer be uniform, which results in inconsistent or non-uniform processing of substrates. The plasma standing wave effect in particular for large plasma reactor is even stronger since the free space excitation frequency increases, the wavelength decreases.

Therefore, there is a need in the art for an approach that can improving electron mobility of a TFT device while substantially maintaining film uniformity in light of the electromagnetic effects occurring at high frequencies.

### SUMMARY OF THE INVENTION

The present invention generally relates to a deposition process that can improving electron mobility of a TFT device, or improving efficiency of tandem junction solar cells, while substantially maintaining film uniformity in light of the electromagnetic effects occurring at high frequencies.

Surprisingly, the standing wave effect of RF frequency is more dominant for N₂-containing plasma such as silicon nitride deposition, while no significant standing wave effect has been observed for amorphous silicon and microcrystalline silicon deposition. Therefore, the film quality can be controlled by varying RF frequency for silicon nitride deposition to maintain the film uniformity and varying VHF frequency for amorphous silicon or microcrystalline silicon deposition to obtain high quality films at high deposition rate.

In one embodiment a method for forming a thin film transistor device in a substrate processing chamber that is capable of creating a plasma environment comprises forming an active layer on a substrate by a method comprising depositing a silicon nitride layer adjacent to the substrate with a first frequency power source, and depositing a semiconductor layer adjacent to the silicon nitride layer with a second frequency power source, and forming a passivation layer adjacent to the active layer by a method comprising depositing a silicon nitride layer adjacent to the semiconductor layer with the first frequency power source.

In another embodiment a method for forming a tandem junction thin film solar cell in a substrate processing chamber that is capable of creating a plasma environment comprises depositing a top cell of amorphous silicon adjacent to a substrate using RF frequency power source, and depositing a bottom cell of microcrystalline silicon adjacent to the top cell using VHF frequency power source.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic diagram of an example capacitively coupled PECVD processing chamber for practicing the present invention.

FIG. 2 is a schematic diagram of another embodiment of an example capacitively coupled PECVD processing chamber for practicing the present invention.

FIG. 3A shows a process sequence which can be used to form a TFT structure.

FIG. 3B shows a schematic side view of a substrate including an example TFT structure.

FIG. 4 is a graph of film deposition rate (Å/min) for a PECVD-deposited SiN film, a-Si film, and mc-Si film, as a function of the distance (mm) across different substrate sizes under a condition of RF frequency.

FIG. 5 is a flow diagram illustrating a method of controlling film quality for amorphous silicon TFTs in accordance with one embodiment of the present invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The following description sets forth numerous specific details such as examples of specific chambers, components, methods, and so forth, in order to provide a good understanding of several embodiments of the present invention. It will be apparent to one skilled in the art that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the spirit and scope of the present invention.

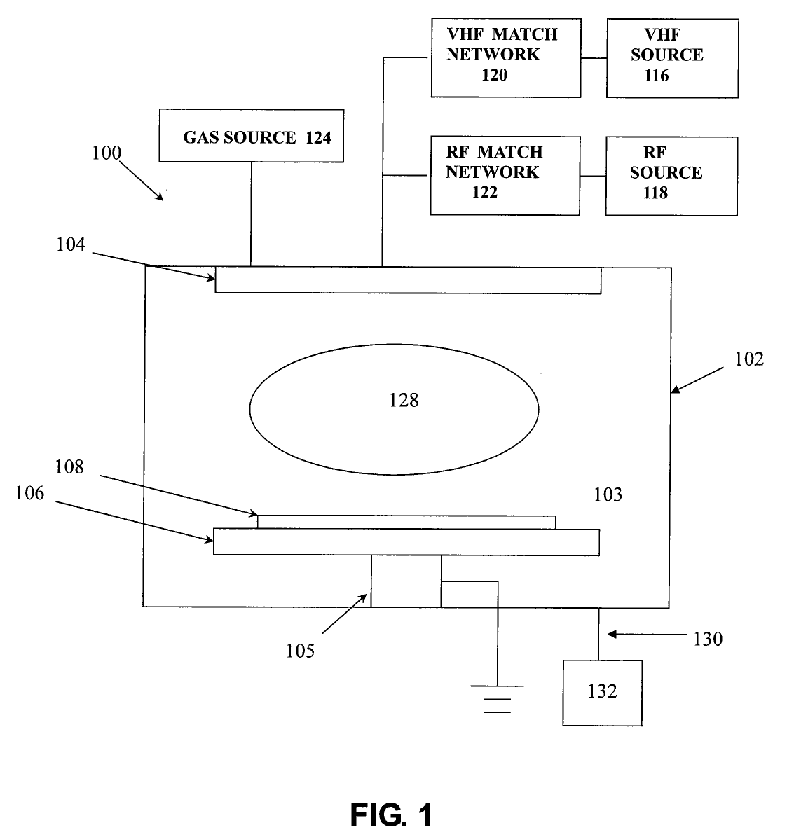

FIG. 1 is a schematic diagram of an example capacitively-coupled (parallel plate) Plasma-Enhanced Chemical Vapor Deposition (PECVD) processing chamber 100 for practicing the present invention. One suitable PECVD chamber is available from Applied Materials, Inc., located in Santa Clara, Calif. It is contemplated that other deposition chambers, including those from other manufacturers, may be utilized to practice the present invention. The processing system 100 may be attached to a processing system platform and may comprise a multi-purpose chamber configured to perform a specific process. Although the invention is described with respect to a particular configuration, it is understood that the invention is applicable in a variety of configurations and designs. For example, in one embodiment a cathode-coupled PECVD chamber, rather than the anode-coupled PECVD chamber as shown in FIG. 1, may be used to benefit the present invention. Further, it is understood that the processing chamber is a simplified schematic representation and some aspects that may be part of the processing chamber 100 are not shown. For example, actuators, valves, sealing assemblies and the like are not shown. Persons skilled in the art will readily recognize that these and other aspects may be incorporated into the processing chamber 100.

The processing chamber 100 generally includes a chamber body 102 having a cavity 103 at least part of which is a processing region. An opening (not shown) may be formed in a wall of the chamber body 102 to facilitate substrate transfers into and out of the processing chamber 100. A bottom of the chamber body 102 may include an outlet 130 for exhausting gases from the chamber body 102. An exhaust system 132 may be attached to the outlet 130 of the bottom of the chamber body 102. The exhaust system 132 may include components such as a throttle valve and a vacuum pump. Once the processing chamber 100 is sealed, exhaust system 132 may be operated to draw and maintain a vacuum within the cavity 103.

A top plate electrode 104 is disposed at an upper end of the chamber body 102. The top plate electrode 104 may include a protective coating which prevents or reduces erosion of the material of the plate electrode 104 caused by the plasma in the chamber. The protective coating may comprise a material such as quartz, sapphire, alumina, SiC, SiN, and Si.

In one embodiment, the top plate electrode 104 may include a showerhead of a gas distribution system. In such a configuration, the top plate electrode 104 may be part of a lid assembly that is adapted to distribute gases into the cavity 103. Accordingly, FIG. 1 shows a gas source 124 coupled to the top plate electrode 104. The gas source 124 may contain a precursor or process gases to be utilized for processing a substrate 108 disposed in the chamber body 102. The gas source 124 may include one or more liquid ampoules containing one or more liquid precursors and one or more vaporizers for vaporizing the liquid precursors to a gaseous state. The gas source 124 may also include a remote plasma cleaning source to provide an in-situ chamber cleaning capability.

While the top plate electrode 104 acts as a top electrode of a parallel plate electrode plasma reactor, a substrate support 106 acts as a lower electrode. The substrate support 106 is disposed in the cavity 103 and may be any structure suitable for supporting the substrate 108 (e.g. a glass substrate), such as an electrostatic chuck or a vacuum chuck. The substrate support 106 may include a support plate (not shown) defining a substrate supporting surface that is generally shaped to match the shape of the substrate 108 supported thereon. The substrate supporting surface is generally rectangular or circular to support a substantially rectangular or circular substrate. In one embodiment, the substrate supporting surface is thermally connected to a substrate temperature control system, such as a resistive heating coil and/or fluid passages connected to a heating or cooling fluid system. The substrate support 106 is mounted on a support stem 105 that connects the substrate support to a lift motor (not shown). The lift motor raises and lowers the substrate support 106 between a lower loading/unloading position and an upper processing position which is closely adjacent to the gas distribution system to provide the desired processing conditions. In one embodiment, the lower electrode 104 and the chamber body 102 may be grounded.

Plasmas are generally produced by introducing a low-pressure process gas into the chamber and then directing electrical energy into the chamber for creating an electric field therein. The electric field creates an electron flow within the chamber which ionizes individual gas molecules by transferring kinetic energy to the molecules through individual electron-gas molecule collisions. The electrons are accelerated within the electric field, producing efficient ionization of the gas molecules. The ionized particles of the gas and the free electrons collectively form gas plasma. The excited gas or gas mixture reacts to form a layer of material on a surface of the substrate.

A low frequency RF power source 118 and a VHF power source 116 may be either connected to the top or bottom electrode for generating and maintaining plasma 128 in the chamber body 102. FIG. 1 illustrates one embodiment of PECVD processing chamber 100 for practicing the present invention where a low frequency RF power source 118 and a VHF power source 116 are connected to a top electrode 104. The low frequency RF power source 118 may be connected to the top electrode 104 through a low frequency match network 122 and the VHF power source 116 may be connected to the top electrode 104 through a VHF match network 120, to enhance deposition or dissociation of the process gases and plasma density. Those of ordinary skills in the art will recognize that each of the match networks 120, 122 may include one or more capacitors, inductors and other circuit components.

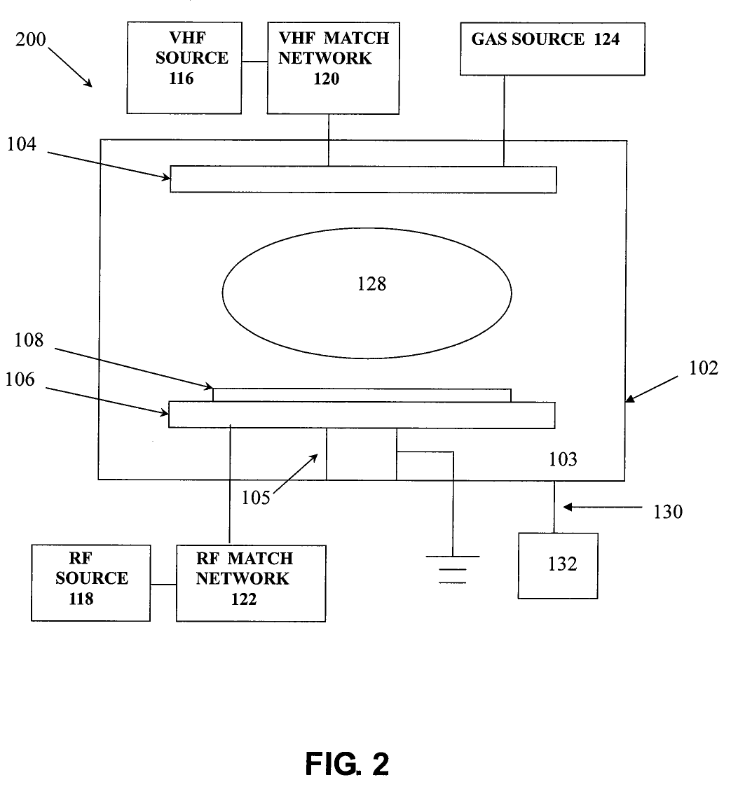

FIG. 2 illustrates another embodiment of PECVD processing chamber 200 for practicing the present invention where the low frequency RF power source 118 and the low frequency match network 122 are connected to a bottom electrode, while the VHF power source 116 and the VHF match network 120 are connected to the top electrode 104, or vice versa. It should be appreciated by persons skilled in the art that other electrode arrangement is possible for practicing the present invention. For example, a single powered electrode PECVD processing chamber may be used where the high and low frequency power supply are electrically coupled to the single electrode and may be switched upon the materials to be deposited in an effort to increase process flexibility.

In either FIG. 1 or FIG. 2, the low frequency RF power source 118 may deliver RF power to the supporting substrate 106 at a frequency at or below about 20 MHz while the VHF power source 116 may deliver VHF power to the supporting substrate 106 at a frequency at or above 20 MHz. In one embodiment, the low frequency RF power source 122 delivers RF power to the supporting substrate 106 at a frequency between about 100 kHz and about 20 MHz while the VHF power source 116 delivers VHF power to the supporting substrate 106 at a frequency between about 40 MHz and about 200 MHz. In another embodiment, the high and low frequencies do not overlap during operation. That is, the low frequency RF power source 118 is operated at a frequency below the frequency of the VHF power source 116. The low frequency RF power and the VHF frequency power may or may not perform at the same time, and frequency range may vary depend on the material to be deposited on the substrate, as will be discussed in detail below.

Fabrication of amorphous silicon or microcrystalline silicon TFTs using PECVD method of the present invention is discussed below. To provide a general understanding of the relationship of the PECVD deposited a-SiNₓ:H gate dielectric film and the a-SiNₓ:H passivation dielectric film relative to the other components of the TFT, a brief description of the overall process is presented below for better understanding of the present invention.

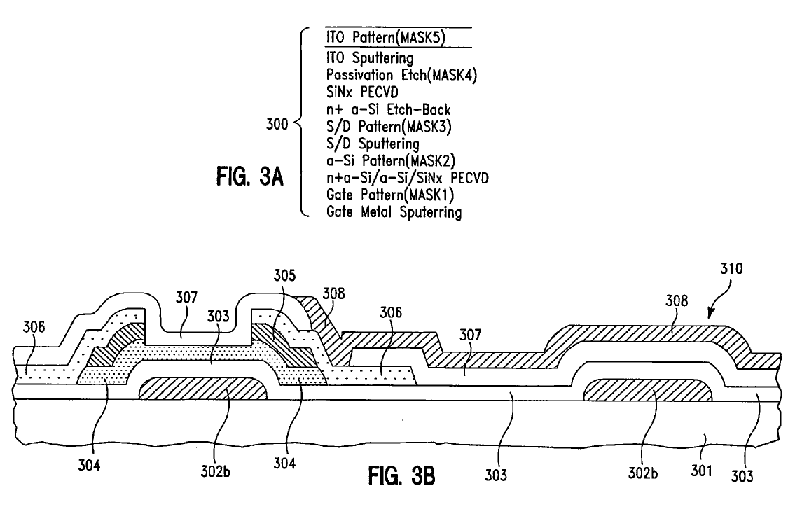

FIG. 3A shows a series of process steps 300 which may be carried out to create the TFT device shown in FIG. 3B in accordance with the present invention. FIG. 3B provides a schematic side view of a substrate including a TFT structure.

In the first step, “Gate Metal Sputtering”, a conductive layer 302b is sputter deposited over a substrate 301 using techniques known in the art. In this particular instance the substrate 301 may be a glass substrate having a desired thickness. The conductive layer 302b is actually a bilayer, where the bottom portion of the layer may be a chrome layer, with an overlying layer of an aluminum neodymium alloy.

In the second step, “Gate Pattern (MASK 1)”, the conductive layer 302b is pattern etched using a wet etch process known in the art to provide conductive electrodes 302b.

In the third step, “n⁺ a-Si/a-Si/a-SiNₓ:H PECVD”, a layer 303 of a-SiNₓ:H is blanket applied by the PECVD process of the present invention, which is described in detail subsequently herein. Following the deposition of layer 303, a layer 304 of a-Si is blanket deposited using the PECVD process of the present invention. Thereafter, a layer 305 of n⁺ doped a-Si is blanket applied by the PECVD process of the present invention, to provide a conductive layer which can later become the source and drain regions for the TFT device. In a microcrystalline silicon TFTs, the layer 304 may be microcrystalline silicon (mc-Si), which can be deposited by the PECVD process of the present invention as well. In one embodiment, the layer 305 can be either a-Si or mc-Si.

In the fourth step, “a-Si Pattern (MASK 2)”, layers 304 of a-Si and 305 of n⁺ doped a-Si are pattern dry etched, using techniques known in the art.

In the fifth step of the process, “S/D Sputtering”, a blanket sputtering deposition of a chrome layer 306 is carried out using techniques known in the art. A portion of the chrome layer 306 subsequently becomes part of the source and drain regions of the TFT device.

In the sixth step, “S/D Pattern (MASK 3)”, chrome layer 306 is pattern dry etched, using techniques known in the art.

In the seventh step of the process, “n⁺ a-Si Etch-Back”, the portion of the n⁺ a-Si layer 305 which was exposed by the patterned dry etch in the sixth step is etched back using techniques known in the art. The n⁺ a-Si layer 305 is etched completely through, and is overetched into underlying layer 304 of a-Si.

In the eighth step of the process, “SiNₓ:H PECVD”, a passivation layer of a-SiNₓ:H dielectric 307 is applied over the substrate surface using PECVD, by the method of the present invention.

In the ninth step of the process, “Passivation Etch (MASK 4)”, the passivation layer of a-SiNₓ:H dielectric 307 is pattern dry etched, using techniques known in the art.

In the tenth step of the process, “ITO Sputtering”, a layer 308 of indium tin oxide is blanket sputter deposited over the substrate using techniques known in the art. The indium tin oxide layer 308 is a conductive optically clear layer when sputter deposited. This optically clear conductive layer enables the use of the TFT device for display applications.

In the eleventh step of the process, “ITO Pattern (MASK 5)”, the indium tin oxide layer 308 is pattern dry etched using techniques known in the art to produce a patterned conductive layer which permits addressing of individual TFT structures.

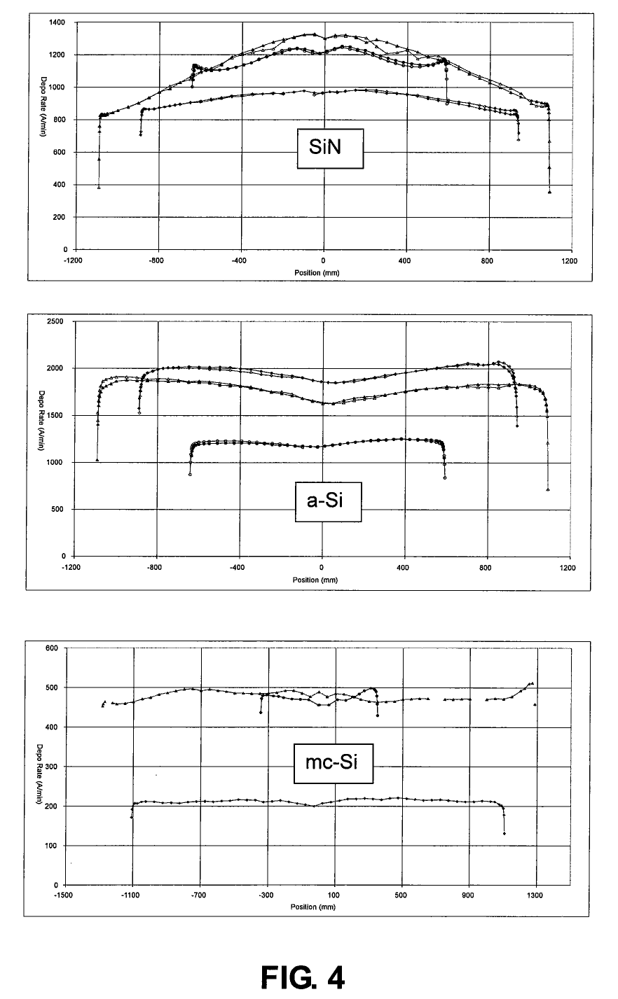

FIG. 4 illustrates the film deposition rate (A/min) for a PECVD-deposited SiN film, a-Si film, and mc-Si film as a function of the distance of travel (mm) across various substrate sizes under RF frequency. As mentioned previously, when the reactors reach a larger size, the plasma density across the reactor is no longer uniform due to the standing wave effect. However, we surprisingly discovered that standing wave effect of RF frequency is more dominant for N₂-containing plasma such as silicon nitride deposition, while amorphous silicon and microcrystalline silicon deposition are relatively less affected by RF standing wave effect. The experiment in FIG. 4 shows that in depositing SiN films the deposition rate dramatically increases in the center area when the substrate size is getting larger, comparing with a-Si or mc-Si film deposition where a slightly dented or flatten deposition is observed in the center of the substrate.

Although the mechanism behind this phenomenon is not clear, a lower frequency plasma for SiN film deposition is preferred since RF standing wave effect is seen only in SiN deposition. In contrast, a higher frequency plasma having lower ion bombardments and increased electron density is desirable during amorphous silicon (or microcrystalline silicon) deposition because it will have less defect density in the film. In addition, although FIG. 4 shows SiN profile at RF frequency a significant “dome” profile for large area chamber due to the standing wave effect, this phenomenon could be further mitigated by designing electrode property, such as hollow cathode gradient, spacing gradient, or flow gradient etc. Example of gas diffuser hole design is disclosed in U.S. Patent Publication No. 2005/0251990 A1, titled “Plasma Uniformity Control by Gas Diffuser Hole Design,” which is hereby incorporated by reference in its entirety. Having recognized these characteristics, it is believed that the film quality can be controlled by adopting RF frequency for silicon nitride deposition to maintain the film uniformity and adopting VHF frequency for amorphous silicon or microcrystalline silicon deposition to obtain high quality film at high deposition rate, as will be discussed below.

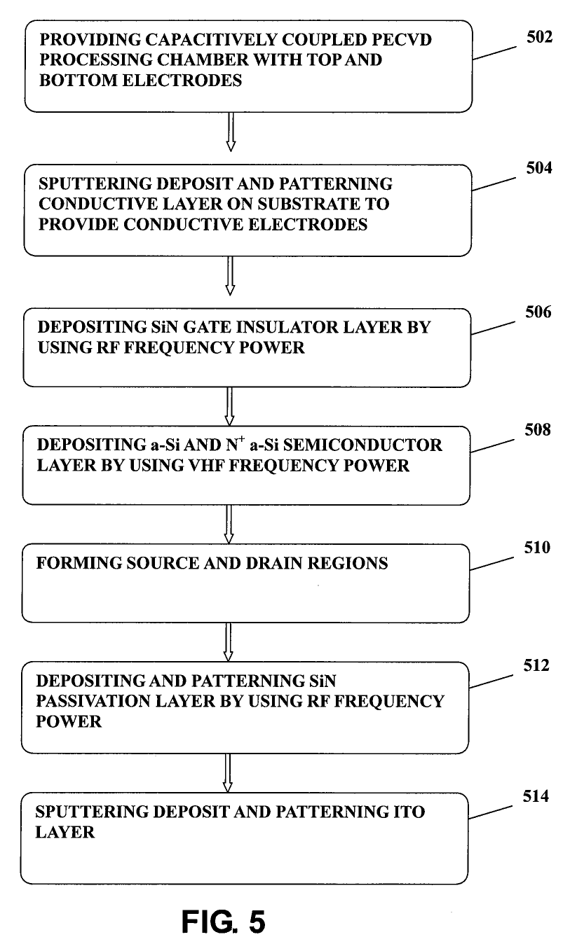

FIG. 5 is a flow diagram illustrating a method of improving film quality for amorphous silicon or microcrystalline silicon TFTs in accordance with one embodiment of the present invention. The processes described below are simplified for clarification and better understanding of the present invention. However, it should be noted that the deposition method described herein is applicable to other device having stacked layers of silicon nitride, amorphous and/or microcrystalline silicon, or materials having similar characteristics, and is not limited to TFT device.

At 502, a capacitively coupled PECVD processing chamber with top and bottom electrodes is provided. The chamber has a top and a bottom planar electrode. The electrodes may be parallel to each other. The bottom electrode may be used to support a substrate to be processed. An example of the capacitively coupled PECVD processing chamber is described above with respect to FIGS. 1 and 2. At 504, a conductive layer is sputter deposited over a substrate using techniques known in the art. The conductive is then pattern etched using techniques known in the art to provide conductive electrodes. At 506, a SiN layer is deposited to act as gate insulators using RF frequency power. Using lower frequency in SiN deposition, as mentioned above, will benefit maintaining a uniform film deposition without being affected by standing wave effect. In one embodiment, the RF frequency power adopted is between about 100 kHz and about 20 MHz. In another embodiment, the RF frequency power is provided at about 13.56 MHz. It is understood that any specific RF frequency range lower than very high frequency may be used to avoid plasma standing wave effect during the deposition of silicon nitride, thereby achieving a more uniform or desirable deposition.

At 508, layers of a-Si and n⁺ doped a-Si are sequentially deposited following the deposition of gate insulators by using VHF frequency power to obtain a high quality and high deposition rate amorphous silicon deposition. Various VHF frequency ranges may be used. In one embodiment, the VHF frequency power is between about 20 MHz and about 200 MHz. In another embodiment, the VHF frequency is between about 40 MHz and about 80 MHz. In yet another embodiment, the VHF frequency power is provided at about 60 MHz.

If microcrystalline silicon TFTs is desired, the semiconductor film may be replaced by microcrystalline silicon to obtain higher electron mobility and hence a faster operation speed. The VHF frequency range remains the same as described above. However, it should be appreciated by persons skilled in the art that other VHF frequency ranges higher than RF frequency may be used upon requirement to improve the mobility of the film.

At 510, layers of a-Si and n⁺ doped a-Si are pattern dry etched using techniques known in the art. Thereafter, a blanket sputtering deposition of a chrome layer, for example, is deposited and then etched to provide source and drain regions for TFT device. At 512, a passivation layer of SiN is applied over the substrate surface using RF frequency power ranging between about 100 kHz and about 20 MHz. In one embodiment, the RF frequency power is about 13.56 MHz. At 514, a layer of indium tin oxide (ITO) is blanket sputter deposited over the substrate using techniques known in the art and then pattern etched to enable the use of the TFT device for display applications.

The approaches described above have been proved to be satisfactory in manufacturing amorphous silicon or microcrystalline silicon TFTs having surface areas as large as about 1870 mm×2200 mm (potentially larger substrate sizes) by showing an improved electron mobility while providing an uniform film deposition in light of the electromagnetic effects occurring at high frequencies.

We have further discovered that the similar approach is effective as well in fabricating thin film solar device, in particular for multi-junction solar cells. Multi-junction cells with different bandgap components, for example, amorphous silicon and micro-crystalline silicon tandem junction device, is known for providing a better utilization of the solar spectrum for thin film solar cells since different portions of the solar spectrum can be converted by each junction at a greater efficiency.

In one embodiment of the present invention, we have fabricated an amorphous silicon and microcrystalline silicon tandem junction device by adopting RF frequency plasma for amorphous silicon deposition and adopting VHF frequency plasma for microcrystalline silicon deposition, or vice versa, so as to achieve an enhanced stability of solar cells, i.e., less light induced degradation, at a relatively higher deposition rate. However, due to the fact that microcrystalline silicon has a much lower absorption coefficient than amorphous silicon and hence requiring a thicker thickness than the top-cell amorphous silicon layer, microcrystalline silicon layer quality typically is more critical in the tandem junction structure. In order to provide a higher electron density and higher deposition, the use of VHF frequency plasma for microcrystalline silicon deposition is much desirable. However, VHF frequency plasma may also be used in depositing both amorphous silicon and microcrystalline silicon, if desired.

The RF frequency power used during amorphous silicon deposition is between about 100 kHz and about 20 MHz. In one embodiment, the RF frequency power is provided at about 13.56 MHz. The VHF frequency power applied during microcrystalline silicon deposition is between about 20 MHz and about 200 MHz. In one embodiment, the VHF frequency is between about 40 MHz and about 80 MHz. In yet another embodiment, the VHF frequency power is provided at about 60 MHz. It should be understood by those skilled in the art that two or more junctions consisting of materials of different bandgaps can be built and deposited in accordance with the present invention to increase solar cell efficiency, i.e., better utilization of the solar spectrum, increased voltage, and enhanced stability while improving the uniformity of the film deposition. For example, the tandem junction structure described herein may comprises a top p-i-n or n-i-p junction comprising a first p-doped layer, an amorphous silicon layer, and a first n-doped layer, and a bottom p-i-n or n-i-p junction comprising a second p-doped layer, a microcrystalline silicon layer, and a second n-doped layer. In one embodiment, the intrinsic “i” region may be undoped or virtually undoped semiconductor region.

Although embodiments of this invention have been shown and described, it is to be understood that various modifications and substitutions, as well as a rearrangement of parts and process steps can be made by those skilled in the art without departing the novel spirit and scope of the present invention. For example, the amorphous silicon and microcrystalline silicon may be hydrogenated amorphous or hydrogenated microcrystalline silicon. Additionally, one or more intermediate layers, such as SiOx, SiOC, or ZnO based intermediate layer, may be formed between the tandem-structured solar cells to achieve a greater efficiency by reflecting the light back to the top cell of the tandem junction device.

It should also be appreciated by those skilled in the art that the arrangement of electrodes is not limited in a way shown in FIGS. 1 or 2. Specifically, when a single powered electrode PECVD processing chamber is used, the RF frequency power and VHF frequency power used during stacked layer deposition may be switched upon the material to be deposited in the same PECVD processing chamber. Alternatively, the first material and the second material may be deposited in two different chambers by moving the substrate from one to another, so that the first material may be deposited using RF frequency plasma at the first chamber and the second material may be deposited using VHF frequency plasma at the second chamber.

While the foregoing is directed to embodiments of the present invention, other and further embodiments of the invention may be devised without departing from the basic scope thereof, and the scope thereof is determined by the claims that follow.

1. A method for forming a thin film transistor device in a substrate processing chamber that is capable of creating a plasma environment, comprising:
forming an active layer on a substrate by a method, comprising:
depositing a silicon nitride layer adjacent to the substrate with a first frequency power source; and
depositing a semiconductor layer adjacent to the silicon nitride layer with a second frequency power source; and
forming a passivation layer adjacent to the active layer by a method, comprising:
depositing a silicon nitride layer adjacent to the semiconductor layer with the first frequency power source.

2. The method of claim 1, wherein the processing chamber is a capacitively-coupled parallel plate plasma reactor.

3. The method of claim 2, wherein the processing chamber has a top electrode and a bottom electrode, where the first and the second frequency power source are electrically coupled to either the top electrode or the bottom electrode, or separately coupled to either the top electrode or the bottom electrode.

4. The method of claim 2, wherein the processing chamber has a single powered electrode and a switch for switching frequency between the first frequency power source and the second frequency power source upon the materials to be deposited.

5. The method of claim 1, wherein deposition of the silicon nitride is performed in a processing chamber different from deposition of the semiconductor layer.

6. The method of claim 1, wherein deposition of the silicon nitride and deposition of the semiconductor layer are performed in the same processing chamber.

7. The method of claim 6, wherein the first frequency power source and the second frequency power source do not function at the same time.

8. The method of claim 1, wherein the semiconductor layer is microcrystalline silicon or amorphous silicon.

9. The method of claim 8, wherein the semiconductor layer and the silicon nitride are passivated by hydrogen.

10. The method of claim 1, wherein the first frequency power source generates a first frequency between about 100 kHz and about 20 MHz.

11. The method of claim 10, wherein the first frequency is about 13.56 MHz.

12. The method of claim 1, wherein the second frequency power source generates a second frequency between about 20 MHz and about 200 MHz.

13. The method of claim 12, wherein the second frequency is between about 40 MHz and about 80 MHz.

14. The method of claim 13, wherein the second frequency is about 60 MHz.

15. A method for forming a tandem junction thin film solar cell in a substrate processing chamber that is capable of creating a plasma environment, comprising:
depositing a top cell of amorphous silicon adjacent to a substrate using RF frequency power source; and
depositing a bottom cell of microcrystalline silicon adjacent to the top cell using VHF frequency power source.

16. The method of claim 15, wherein the processing chamber is a capacitively-coupled parallel plate plasma reactor.

17. The method of claim 15, wherein the top cell is deposited using VHF frequency.

18. The method of claim 15, wherein the top cell is a p-i-n or n-i-p junction comprising a first p-doped layer, an amorphous silicon layer, and a first n-doped layer, and the bottom cell is a p-i-n or n-i-p junction comprising a second p-doped layer, a microcrystalline silicon layer, and a second n-doped layer.

19. The method of claim 18, wherein the amorphous silicon and the microcrystalline silicon are passivated by hydrogen.

20. The method of claim 15, wherein the RF frequency is between about 100 kHz and about 20 MHz, and the VHF frequency is between about 20 MHz and about 200 MHz.

21. The method of claim 20, wherein the RF frequency is about 13.56 MHz.

22. The method of claim 20, wherein the VHF frequency is about 60 MHz.

23. The method of claim 15, wherein the plasma reactor has a top electrode and a bottom electrode, where the RF and the VHF frequency power source are electrically coupled to either the top electrode or the bottom electrode, or separately coupled to either the top electrode or the bottom electrode.

24. The method of claim 15, wherein the plasma reactor has a single powered electrode and a switch for switching frequency between the first frequency power source and the second frequency power source upon the materials to be deposited.

25. The method of claim 15, wherein deposition of the top cell and deposition of the bottom cell are performed in the same plasma reactor.
